(19) United States
(12) Patent Application Publication
(10) Pub. No.: US 2026/0130298 A1
(43) Pub. Date: May 7, 2026

(54) SUBSTRATE BONDING WITH LOCAL BONDING REGION SHAPE CONTROL

(71) Applicant: Tokyo Electron Limited, Tokyo (JP)

(72) Inventors: Christopher Michael Netzband, Albany, NY (US); Michael Murphy, Niskayuna, NY (US); Ilseok Son, Albany, NY (US)

(21) Appl. No.: 18/939,717

(22) Filed: Nov. 7, 2024

(51) Int. Cl. H01L 23/00

(52) U.S. Cl. CPC H10W 99/00; H10W 72/0198; H10W 72/931; H10W 80/312; H10W 80/327

(57) ABSTRACT

A method of bonding a smaller substrate, such as a die, to a larger substrate, such as a wafer. The method includes forming a bulge at a front side of the larger substrate by releasably securing a backside of the larger substrate to a rigid chuck, bonding the smaller substrate to the bulge at the front side of the larger substrate, and allowing the bulge to flatten by releasing the larger substrate from the rigid chuck. A variable thickness material on the backside of the larger substrate induces the bulge at the front side of the larger substrate. The method may also include forming the variable thickness material on the backside of the larger substrate. Multiple bulges may be induced at the front side of the larger substrate. Multiple smaller substrates may be bonded to a single bulge.

### TECHNICAL FIELD

The present invention relates generally to the field of semiconductor manufacturing, and, more specifically, to substrate bonding processes.

### BACKGROUND

In the semiconductor industry, technological advancement has historically been achieved by scaling down generational technology nodes to ever smaller features and critical dimensions. In recent years, due to a variety of factors including increasing cost and complexity of nodes in nanometer ranges, heterogenous integration of different semiconductor parts into advanced packages has become an increasingly important economic factor in the semiconductor industry. In particular, a need for ever greater numbers of transistors in applications that push performance limits, such as high-performance computing, artificial intelligence (AI)/machine learning (ML), machine vision, and autonomous vehicles and robots, among others, has made such advanced heterogenous packages more economically important. The economic advantages of heterogenous integration can include the ability to combine or mix semiconductor parts from different technology nodes into a single package. In this manner, the complexity or scope of portions of the single heterogenous package that utilize the latest but most resource-intensive technology nodes (e.g., 7 nm or 3 nm nodes) can be reduced or minimized, which can lead to overall economic optimization.

Two or more substrates, such as dies and/or wafers (e.g., already including structures, such as devices, interconnects, and bonding pads), may be bonded together (e.g., stacked) to mix different technology nodes in a single final product for economic benefits. For example, the semiconductor industry has embraced three-dimensional (3D) packaging to enable hybrid devices. 3D integrated circuits (ICs) are often fabricated using substrate bonding processes that produce multiple 3D ICs or chips in a single operation, which can then be diced apart from the bonded wafer structure. Substrate bonding processes may be direct (i.e., there is no intervening separate material between the bonded surfaces of the substrates) and may take place between substrate of the same or different sizes. Some examples of substrate bonding processes involving dies and wafers (common substrates in the semiconductor industry) include wafer-to-wafer (W2W), die-to-wafer (D2W), or die-to-die (D2D), which involve bonding an entire wafer to another entire wafer, bonding at least one die to an entire wafer, or bonding at least one die to another die, respectively.

During substrate bonding processes, precise alignment and bonding of multiple layers is crucial to ensure the functionality and performance of the final device(s). Bonding misalignment refers to the misplacement or mis-registration of patterns and features between different layers during a substrate bonding process. This misalignment can result in various issues such as reduced device yield, degraded electrical performance, and increased fabrication costs. There are components of bonding misalignment, some of which include scaling, translation (i.e., XY positioning error), and rotation. Scaling refers to differences in size and shape between the bonded substrates and may be caused by stretching of one substrate related to the other substrate during the bonding process. Scaling can account for a large proportion of the total distortion budget (i.e., the acceptable amount of distortion to ensure that features on the substrates are sufficiently aligned). Therefore, improved bonding processes that reduce substrate scaling during the bonding process may be desirable.

### SUMMARY

In accordance with an embodiment of the invention, a method of bonding a smaller substrate to a larger substrate includes forming a bulge at a front side of the larger substrate by releasably securing a backside of the larger substrate to a rigid chuck, bonding the smaller substrate to the bulge at the front side of the larger substrate, and allowing the bulge to flatten by releasing the larger substrate from the rigid chuck. A variable thickness material on the backside of the larger substrate induces the bulge at the front side of the larger substrate.

In accordance with another embodiment of the invention, a method of bonding a die to a wafer includes forming a variable thickness material on a backside of the wafer, forming a bulge at a front side of the wafer by releasably securing the backside of the wafer to a rigid chuck, bonding the die to the bulge at the front side of the wafer, and allowing the bulge to flatten by releasing the wafer from the rigid chuck. The variable thickness material includes at least one locally thicker region. The at least one locally thicker region induces the bulge at the front side of the wafer.

In accordance with still another embodiment of the invention, a method of bonding a plurality of dies to a wafer includes forming a plurality of bulges on a front side of the wafer by releasably securing a backside of the wafer to a rigid chuck, bonding the plurality of dies to respective ones of the plurality of bulges on the front side of the wafer, and allowing the plurality of bulges to flatten by releasing the wafer from the rigid chuck. A variable thickness material on the backside of the wafer induces the plurality of bulges on the front side of the wafer.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example bonding process that includes bonding a smaller substrate, such as a die, to a bulge at a front side of a larger substrate, such as a wafer, where the bulge is induced by a variable thickness material on a backside of the larger substrate in accordance with embodiments of the invention;

FIG. 2 illustrates a conventional bonding process where a smaller substrate is bonded to a flat surface of a larger substrate resulting in undesirable scaling distortion between the substrates;

FIG. 3 illustrates an example bonding process that includes bonding a smaller substrate to a bulge at a front side of a larger substrate to compensate for scaling of the smaller substrate in accordance with embodiments of the invention;

FIG. 4 illustrates an example bonding process that includes forming a bulge at a front side of a larger substrate using a locally thick region of a variable thickness material formed on a backside of the larger substrate by releasably securing the larger substrate to a rigid chuck where the locally thick region is a raised structure of substantially constant thickness in accordance with embodiments of the invention;

FIG. 5 illustrates another example bonding process that includes forming a bulge at a front side of a larger substrate where the locally thick region is a raised structure formed on a backside film in accordance with embodiments of the invention;

FIG. 6 illustrates still another example bonding process that includes forming a bulge at a front side of a larger substrate where the locally thick region is a step pyramid structure in accordance with embodiments of the invention;

FIG. 7 illustrates yet another example bonding process that includes forming a bulge at a front side of a larger substrate where the locally thick region is a raised structure substantially corresponding to the bulge shape in accordance with embodiments of the invention;

FIG. 8 illustrates an example bonding process that includes bonding multiple smaller substrates, such as dies, to corresponding bulges at a front side of a larger substrate, such as a wafer, where the bulges are induced by a variable thickness material on a backside of the larger substrate in accordance with embodiments of the invention;

FIG. 9 illustrates an example bonding process that includes bonding multiple differently sized smaller substrates to a front side of a larger substrate using a variable thickness material on the backside of the larger substrate in accordance with embodiments of the invention;

FIG. 10 illustrates an example bonding process that includes bonding multiple differently shaped smaller substrates to a front side of a larger substrate using a variable thickness material on the backside of the larger substrate in accordance with embodiments of the invention;

FIG. 11 illustrates an example method of bonding a smaller substrate to a larger substrate in accordance with embodiments of the invention;

FIG. 12 illustrates an example method of bonding a smaller substrate to a larger substrate that includes a variable thickness material with a locally thicker region that has an alternative shape in accordance with embodiments of the invention;

FIG. 13 illustrates another example method of bonding a smaller substrate to a larger substrate that includes a variable thickness material with a locally thicker region that has an alternative shape in accordance with embodiments of the invention; and

FIG. 14 illustrates an example bonding process that includes bonding multiple smaller substrates to a bulge at a front side of a larger substrate where the bulge is induced by a variable thickness material on a backside of the larger substrate in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Scaling can occur during substrate bonding processes when the bond propagates across a stretched surface of a substrate. Faster propagation of the bond may increase scaling. During substrate bonding of a smaller substrate, such as a die, to a larger substrate, such as a wafer (e.g., a carrier wafer), there is a large amount of scaling (dilation). For example, during D2W bonding, scaling may account for 30% or more of the total distortion budget, before factoring in other distortion concerns, such as translation, rotation, and residuals.

During the substrate bonding process, the bonding surfaces are brought close to one another without touching, which creates a bond gap (e.g., to avoid “crashing” onto the lower surface potentially damaging or destroying sensitive structures). A point on the released substrate (e.g., the center of the upper substrate) is pushed towards the lower substrate to overcome the bond gap, which stretches the surface of the substrate. Once bonding is initiated, the bond propagates outward causing the released wafer to grow in size. For example, bonding initiated from the center of a circular upper wafer produces uniform dilation of the upper wafer.

Scaling can be reduced or corrected for during W2W bonding by using a flexible wafer chuck. Specifically, by flexing the entire bonding surface of the lower chuck into a convex surface (i.e., a bulge shape) a symmetrical stretch of the lower wafer can be induced. If the lower chuck flex amount is correct then the two wafers will be the same size after bonding has completed and there will be no scaling issues. Such wafer level scaling correction is not appropriate for D2W bonding because the wafer is virtually flat at the length scale of an individual die. If the die is held flat during bonding, then scaling can be reduced but bond initiation will occur randomly across the wafer introducing significant uncorrectable residual misalignment. There is currently no solution that addresses the scaling issue for D2W bonding (e.g., from the carrier wafer side).

In accordance with embodiments herein described, the invention proposes using a variable thickness material formed on the backside of a larger substrate (e.g., a wafer) to induce one or more bulges at the front side of the substrate when releasably securing the backside of substrate to a rigid chuck (e.g., a highly flat and rigid chuck). Each bulge is a locally raised region of the front side of the larger substrate and corresponds to a respective smaller substrate (e.g., a die) that will be subsequently bonded to the front side of the substrate. The altered shape of the front side of the substrate is used to compensate for scaling of individual regions (e.g., individual die regions) during a bonding process.

In various embodiments, a method of bonding a smaller substrate to a larger substrate includes forming a bulge at a front side of the larger substrate (e.g., a wafer), bonding a smaller substrate (e.g., a die) to the bulge, and allowing the bulge to flatten. The bulge is formed by releasably securing a backside of the larger substrate to a rigid chuck (e.g., a highly flat and rigid chuck). A variable thickness material (e.g. a photoresist, a dielectric material, such as an oxide, nitride, oxynitride, etc.) on the backside of the larger substrate induces the bulge at the front side of the larger substrate. The bulge is allowed to flatten by releasing the larger substrate from the rigid chuck.

In various embodiments, multiple smaller substrates (e.g., multiple dies) may be bonded to the larger substrate, each with a corresponding bulge. The smaller substrates may be of similar size and shape, or may have different sizes and or shapes. That is, the variable thickness material may be configured to induce individually-tailored bulges corresponding to any desired size and shape.

The variable thickness material may be any material suitable to induce the bulge at the front side, such as a photosensitive material that is patterned using photolithography to form the variable thickness material at the backside of the substrate, or a dielectric material (e.g., an oxide, nitride, oxynitride, etc.) that can be removed after the bonding process. For example, one or more techniques may be used to form the variable thickness material, such as multiple exposure/develop cycles of photolithography, whether with the same or different masks (multipatterning), local differences in the exposure dose (variable exposure), and others. In some embodiments, the variable thickness material is a film that covers the entire backside of the larger substrate. In other embodiments, the variable thickness material only covers parts of the backside, such as in regions aligning the bulge(s).

The embodiment bonding processes described herein may provide various advantages over conventional bonding processes. For example, the embodiment bonding processes may advantageously provide individualized scaling compensation for one or more smaller substrates, such as in a D2W bonding process. The variable thickness material may advantageously replicate the effects of a flexible chuck while using a rigid chuck. Additionally, using the variable thickness material to induce the bulges may have the advantage of being less expensive to modify for different bonding configurations, such as in comparison to a rigid chuck with raised portions, because the same rigid chuck can be used for any configuration. The embodiment bonding processes may also have the benefit of allowing multiple smaller substrates with different sizes and/or shapes to be bonded to a single larger substrate with individualized scaling compensation.

In conventional bonding processes, the die substrate is bulged to ensure proper center bond initiation, but this induces even more scaling and residuals due to any nonuniformity in the shaping of the die holder. Another potential advantage of the embodiment processes described herein may be that a flat holder may be used for the smaller substrate (e.g., a flat die holder) and proper center initiation may be maintained by creating a bulge in the larger substrate (e.g., a wafer mounted on a lower chuck). This may in turn have the benefit of lowering the total scaling in the system and residuals induced by die holder flatness.

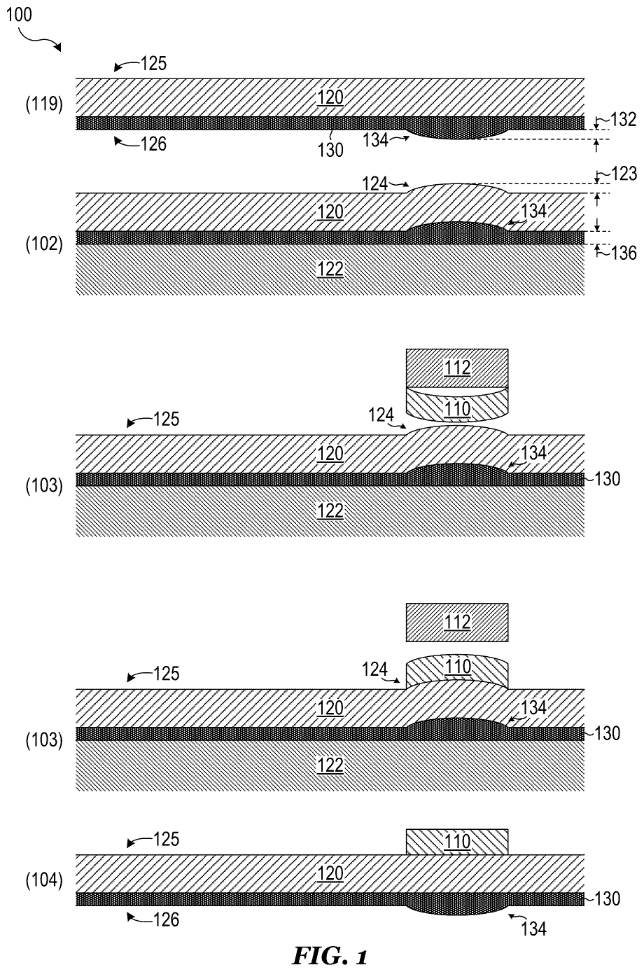

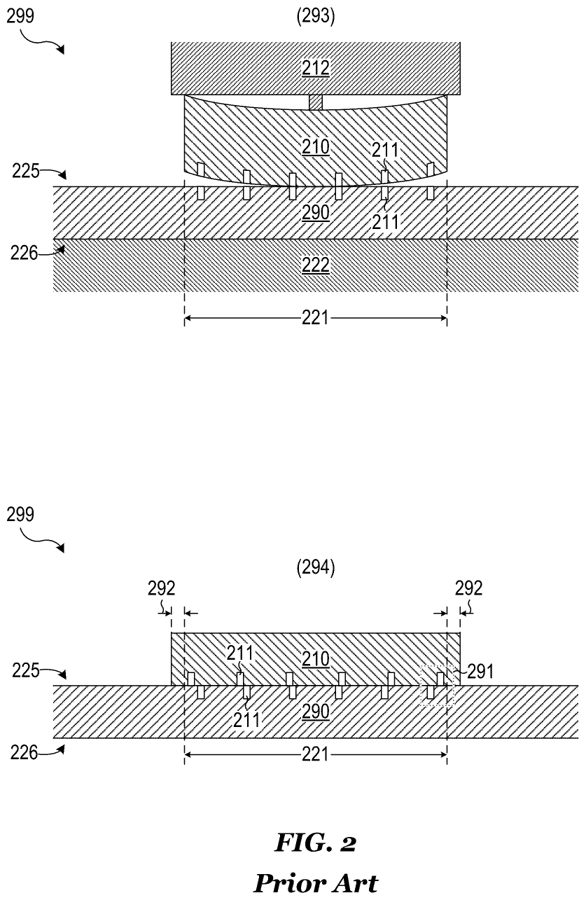

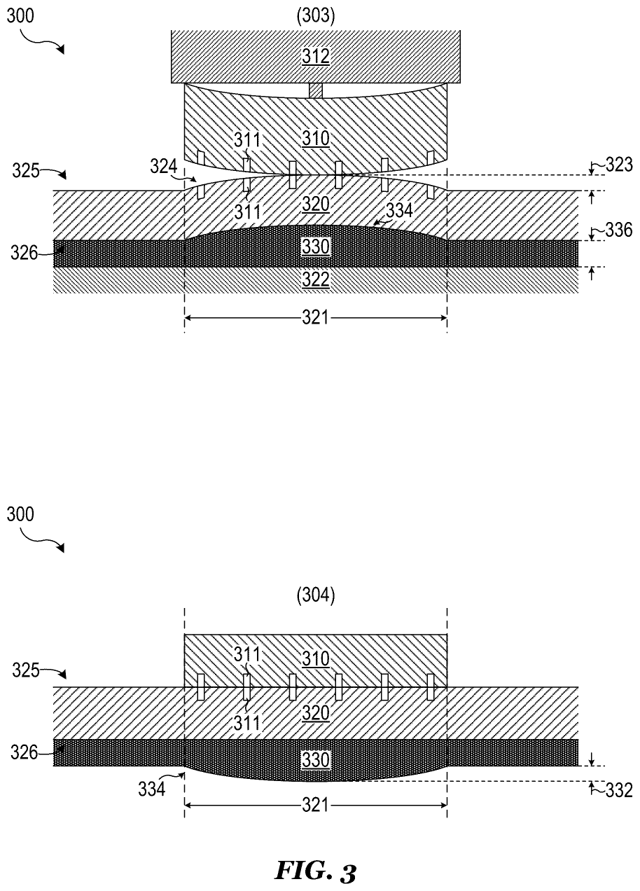

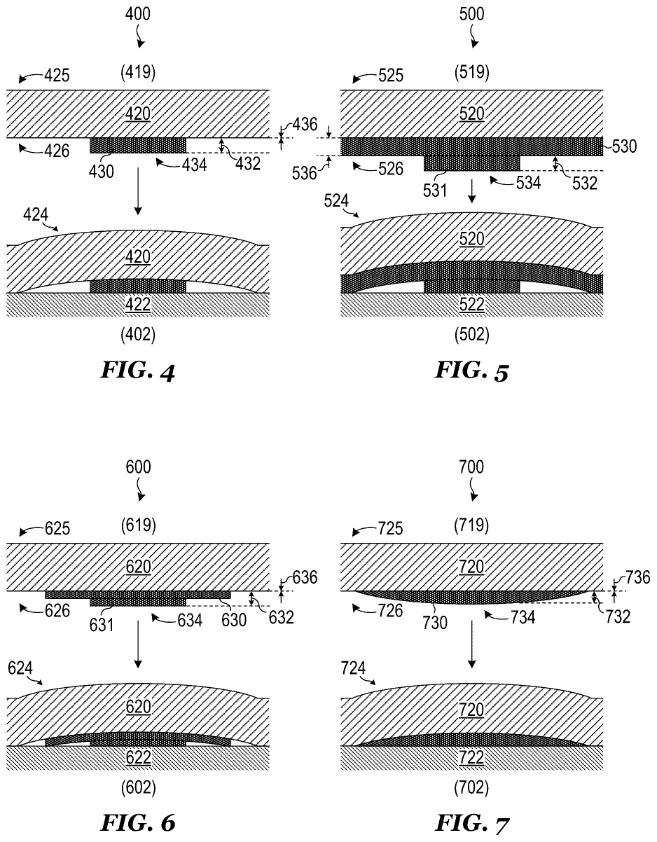

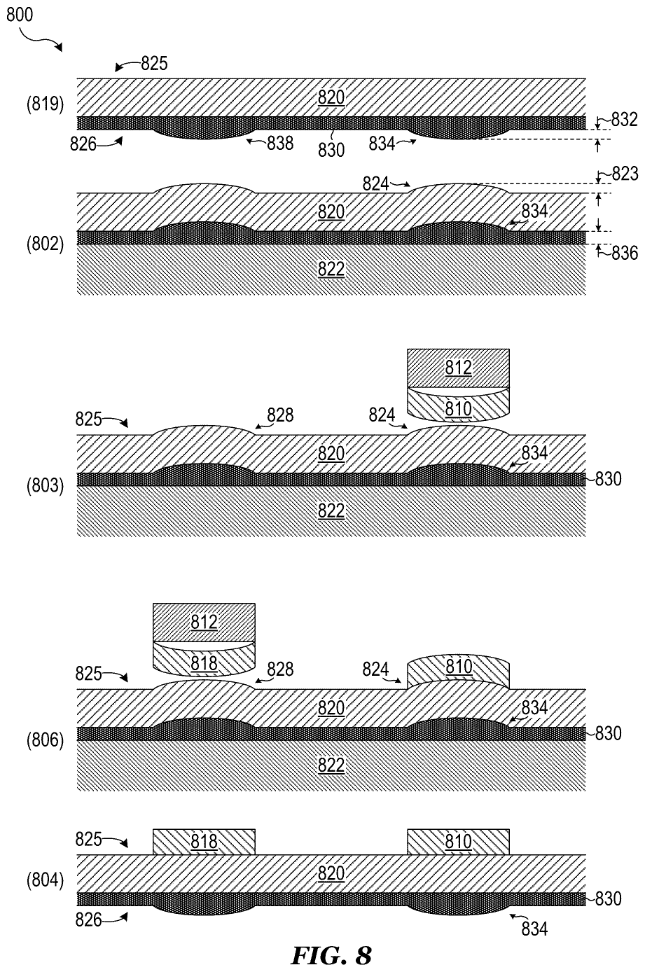

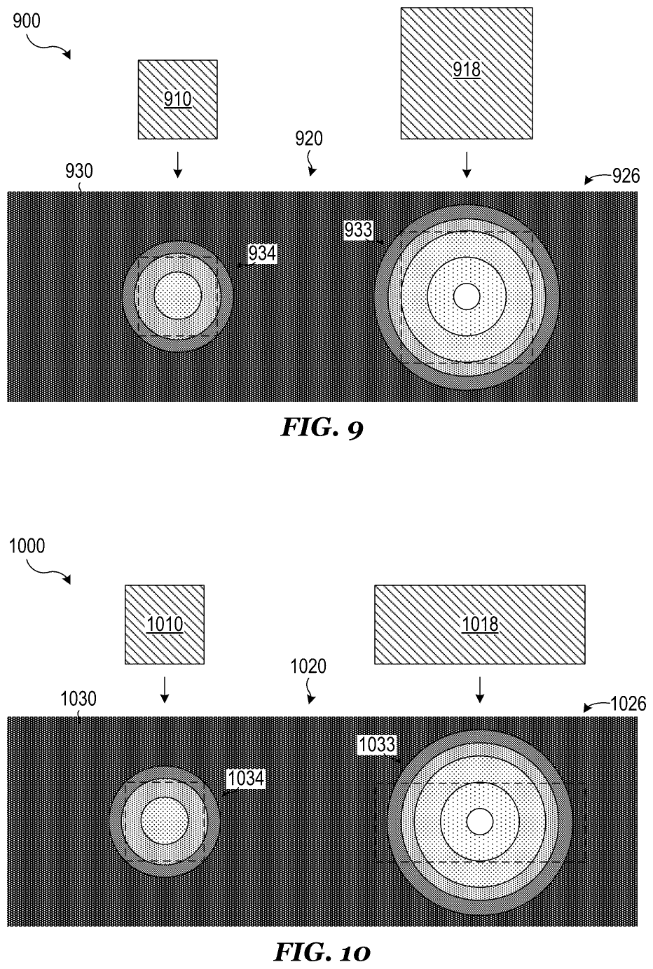

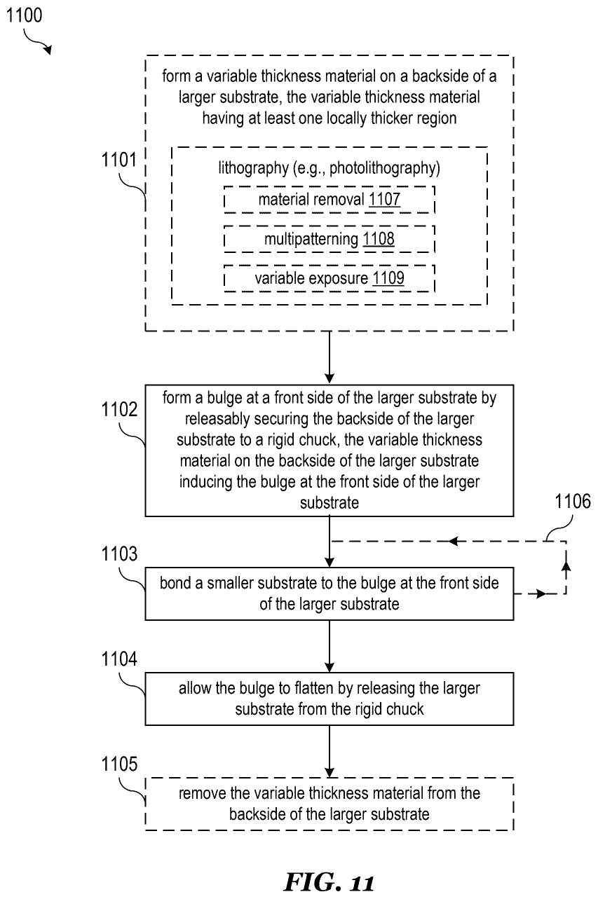

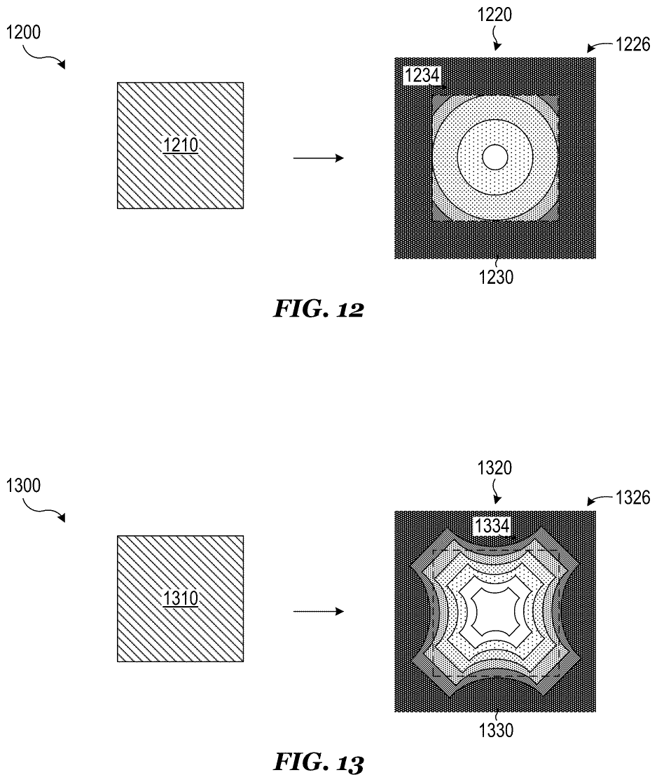

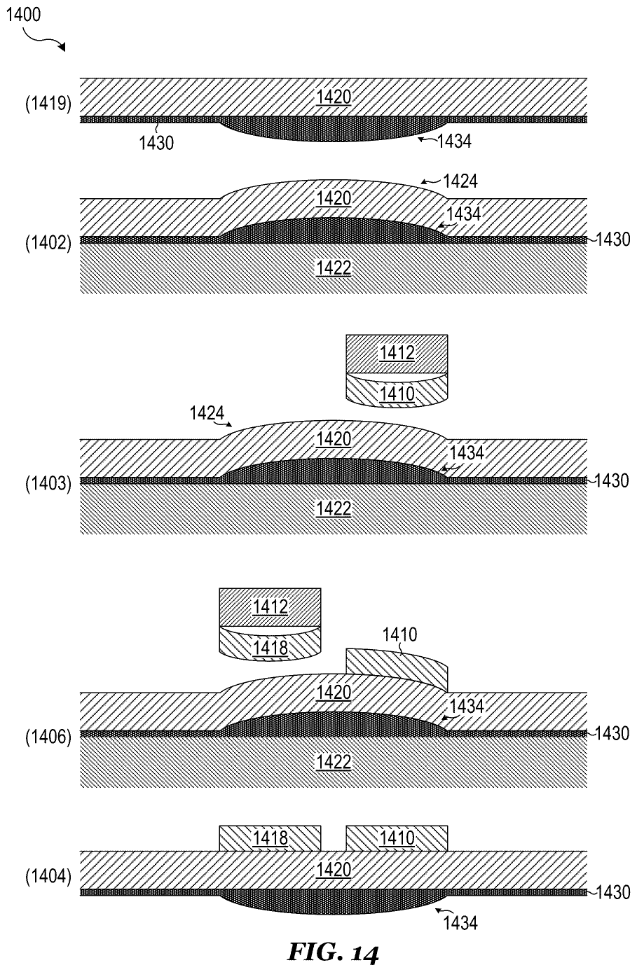

Embodiments provided below describe various bonding processes where one or more smaller substrates are bonded to a larger substrate, and in particular embodiments, bonding processes that include bonding a smaller substrate to a bulge at a front side of a larger substrate that is induced by a variable thickness material on a backside of the larger substrate. The following description describes the embodiments. FIG. 1 is used to describe an example bonding process. FIGS. 2 and 3 are used to compare an example bonding process to a conventional bonding process. Four example bonding processes showing various structures of the variable thickness material are described using FIGS. 4-7. An example bonding process where multiple smaller substrates are bonded to a larger substrate is described using FIG. 8. Two more example bonding processes with differently dimensioned smaller substrates are described using FIGS. 9 and 10 while and an example method of bonding a smaller substrate to a larger substrate is described using FIG. 11. Two more example bonding processes showing alternative shapes for a locally thicker area are described using FIGS. 12 and 13 while FIG. 14 is used to describe an example bonding process where multiple smaller substrates are bonded to a single bulge of a larger substrate.

FIG. 1 illustrates an example bonding process that includes bonding a smaller substrate, such as a die, to a bulge at a front side of a larger substrate, such as a wafer, where the bulge is induced by a variable thickness material on a backside of the larger substrate in accordance with embodiments of the invention.

Referring to FIG. 1, a bonding process 100 begins with a larger substrate 120 in an initial state 119 where a variable thickness material 130 (e.g., a photosensitive material or dielectric material, such as an oxide, nitride, oxynitride, etc.) is disposed on a backside 126 of the larger substrate 120. The variable thickness material 130 has at least one locally thicker region 134 that is thicker than a film thickness 136 of other regions of the variable thickness material 130. For example, each locally thicker region 134 may be thicker than the film thickness 136 (i.e., a baseline thickness, that may be zero, such as when isolated structures of the variable thickness material 130 are formed on the backside 126 of the larger substrate 120). In various embodiments, the bonding process 100 includes the formation of the variable thickness material 130, but the bonding process 100 may also begin with the larger substrate 120 in the initial state 119, as shown.

In the initial state 119, a front side 125 of the larger substrate 120 is substantially flat. During a chucking step 102, the larger substrate 120 is releasably secured to a rigid chuck 122. In one embodiment, the larger substrate 120 is secured using a vacuum chucking process, but other methods of releasably securing the larger substrate 120 are also possible. Because the rigid chuck 122 is resistant to physical deformation, the backside 126 of the larger substrate 120 is forced to substantially take on the shape of the rigid chuck 122 (e.g., a highly flat surface, for example). As a result, the locally thicker region 134 of the variable thickness material 130 is pushed upward and a bulge 124 is formed at the front side 125 of the larger substrate 120.

During a bonding step 103, an upper chuck 112 is used to bond a smaller substrate 110 to the bulge 124 at the front side 125 of the larger substrate 120. For example, the upper chuck 112 may be another rigid chuck onto which the smaller substrate 110 has been releasably secured. The smaller substrate 110 may then be brought into close proximity to the bulge 124 and a bond may be initiated that results in the smaller substrate 110 being bonded to the bulge 124 of the larger substrate 120. Due to the bonding process (which is subsequently discussed in more detail) the smaller substrate 110 may have some degree of curvature when the bond is formed. The curvature of the smaller substrate 110 may substantially mirror that of the bulge 124 (as shown). In some embodiments, the curvatures may be somewhat different. Even in these cases, some benefit of reducing undesirable scaling effects may still be gained to bonding the smaller substrate 110 to a curved surface of the bulge 124.

Although labeled as an “upper” chuck for convenience, it should be noted that there is no limitation on the spatial relationship between the rigid chuck 122 and the upper chuck 112. The upper chuck 112 may be any suitable chuck, and may be used to bond additional smaller substrates to the larger substrate 120 in various embodiments, such as during a pick and place bonding process.

The bulge 124 has a bulge height 123, which is related to a step height 132 of the locally thicker region 134, but may or may not be precisely the same. This is also of course true of the shape of the bulge 124 in comparison to the shape of the locally thicker region 134. The details of the relationship between the locally thicker region 134 and the bulge 124 may depend on a variety of factors that are specific to a given application, such as the material composition and dimensionality of the larger substrate 120 and the variable thickness material 130, among other factors. The size and shape of the bulge 124 is selected based on the smaller substrate 110, and the specific details of the locally thicker region 134 are determined accordingly.

After the smaller substrate 110 has been bonded to the bulge 124 at the front side 125, the larger substrate 120 is released from the rigid chuck 122 during a dechucking step 104. Without the rigid chuck 122 applying force to the variable thickness material 130, The front side 125 of the larger substrate 120 relaxes back to (or at least towards) the substantially flat surface of the initial state 119. At this stage, the variable thickness material 130 may be removed from the backside 126 of the chucking step 102, if desired.

The bonding process 100 may have the advantage of providing scaling compensation for the individual bonding region of the smaller substrate 110 (e.g., an individual die region bonded to a wafer, such as a carrier wafer). The use of the bulge 124 on the backside 126 of the larger substrate 120 counters the curvature of the smaller substrate 110 that is present during the bonding step 103.

FIGS. 2 and 3 are used to compared conventional bonding processes to embodiment bonding processes. FIG. 2 illustrates a conventional bonding process where a smaller substrate is bonded to a flat surface of a larger substrate resulting in undesirable scaling distortion between the substrates.

Referring to FIG. 2, a conventional bonding process 299 includes a conventional bonding step 293 during which a smaller substrate 210 (e.g., already including electrical connections 211) is bonded to a front side 225 of a conventional larger substrate 290. Prior to the bond being initiated, the smaller substrate 210 is releasably secured to an upper chuck 212 while a backside 226 of the conventional larger substrate 290 is releasably secured to a rigid chuck 222. The smaller substrate 210 is bonded to a bonding region 221 of the conventional larger substrate 290.

During the conventional bonding step 293, the smaller substrate 210 is brought close to the conventional larger substrate 290, but does not make contact (such as to avoid crashing into the conventional larger substrate 290 and damaging one or both of the smaller substrate 210 and the conventional larger substrate 290). The center region of the smaller substrate 210 is then bowed out to meet the conventional larger substrate 290 and initiate the bonding process, creating a curvature in the smaller substrate 210. Notably, the straight-line distance from one edge of the smaller substrate 210 to an opposing edge is now greater due to the curvature (i.e., the surface is stretched).

After the bond is initiated, the bond propagates from the center of the smaller substrate 210 to the edges resulting in the smaller substrate 210 being bonded to the front side 225 of the conventional larger substrate 290. However, the stretched state from the curvature of the smaller substrate 210 is at least partially maintained (the exact degree may depend on the properties of the bond propagation and the relaxation, such as speed, compared to the time it takes for the smaller substrate 210 to return to its initial shape). As a result, the bonded smaller substrate 210 is now larger (scaled) compared to the bonding region 221 and undesirable scaling 292 is present, even after the conventional larger substrate 290 is released from the rigid chuck 222 during a conventional dechucking step 294. Moreover, the undesirable scaling 292 may result in undesirable misalignment 291 where the electrical connections 211 are not aligned resulting in open circuits or improper connections.

In contrast, FIG. 3 illustrates an example bonding process that includes bonding a smaller substrate to a bulge at a front side of a larger substrate to compensate for scaling of the smaller substrate in accordance with embodiments of the invention. The bonding process of FIG. 3 may be a specific implementation of other bonding processes described herein such as the bonding process of FIG. 1, for example. Similarly labeled elements may be as previously described.

Referring to FIG. 3, a bonding process 300 includes a bonding step 303 during which a smaller substrate 310 (e.g., already including electrical connections 311) is bonded to a bulge 324 at a front side 325 of a larger substrate 320. It should be noted that here and in the following a convention has been adopted for brevity and clarity wherein elements adhering to the pattern [x20] where ‘x’ is the figure number may be related implementations of a larger substrate in various embodiments. For example, the larger substrate 320 may be similar to the larger substrate 120 except as otherwise stated. An analogous convention has also been adopted for other elements as made clear by the use of similar terms in conjunction with the aforementioned numbering system.

The bulge 324 of the larger substrate 320 is induced by a locally thicker region 334 of a variable thickness material 330 that is disposed on a backside 326 of the larger substrate 320 by virtue of the larger substrate 320 being releasably secured to a rigid chuck 322. For example, the bulge 324 has a bulge height 323 that is related to a step height 332 of the locally thicker region 334 above a film thickness 336 of the variable thickness material 330 (which may be zero). Consequently, the curvature of the front side 325 is locally substantially similar to the curvature of the smaller substrate 310 as bonding is initiated, such as by bowing out the center region of the smaller substrate 310 from an upper chuck 312 to which the smaller substrate 310 is releasably secured.

The purpose of the bonding process 300 is to bond the smaller substrate 310 to a bonding region 321 of the larger substrate 320. The size and location of the bulge 324 at the front side 325 of the larger substrate 320 is related to the size and location of the bonding region 321. However, one or both of the size and shape of the bulge 324 may be the same or different than that of the bonding region 321 in various embodiments. For example, in some embodiments, the extent of the bulge 324 and the bonding region 321 are substantially similar (as shown), but the shape is different, such as when the bulge 324 is substantially circular, and the smaller substrate 310 includes substantially straight edges (e.g., is a square, rectangle, etc.).

The bonding step 303 may use any suitable type of bonding technique. One type of bonding is metal-to-metal bonding. Another type of bonding process is fusion bonding, where two substrate surfaces are brought into intimate contact at room temperature and then annealed at higher temperatures (e.g., 800-1200° C.) to form strong covalent bonds. Fusion bonding may be used in a variety of applications, including silicon-on-insulator (SOI) fabrication, microelectromechanical devices (MEMS), nanoelectromechanical devices (NEMS), and others. Yet another (similar) type of bonding process is known as hybrid bonding and combines aspects of fusion bonding with metal-to-metal bonding. Specifically, hybrid bonding simultaneous bonds dielectric materials and metal materials, such as interconnects. Hybrid bonding may be used in applications where a bond between the substrate themselves is desired and electrical contact between the two substrates is also desired, such as for three-dimensional integration (3DI) in advanced packaging applications.

During a dechucking step 304, the larger substrate 320 is released from the rigid chuck 322 and the variable thickness material 330 is allowed to relax toward its initial state. The bulge 324 also relaxes (in some cases back to the original flatness of the front side 325 before the bulge 324 was formed, in other cases to somewhere in between). Since both surfaces of the smaller substrate 310 and the larger substrate 320 were stretched during the bonding step 303, scaling distortion between the smaller substrate 310 and the larger substrate 320 is reduced or eliminated, as illustrated. The electrical connections 311 therefore remain aligned, unlike in conventional bonding processes.

FIGS. 4-7 illustrate example bonding processes that include forming a bulge at a front side of a larger substrate using a locally thick region of a variable thickness material formed on a backside of the larger substrate by releasably securing the larger substrate to a rigid chuck in accordance with embodiments of the invention. FIG. 4 shows a locally thick region that is a raised structure of substantially constant thickness, FIG. 5 shows a locally thick region that is a raised structure formed on a backside film, FIG. 6 shows a locally thick region that is a step pyramid structure, and FIG. 7 shows a locally thick region that is a raised structure substantially corresponding to the bulge shape. Each of the bonding process of FIGS. 4-7 may be a specific implementation of other bonding processes described herein such as the bonding process of FIG. 1, for example. Similarly labeled elements may be as previously described.

Referring to FIG. 4, a bonding process 400 begins with a larger substrate 420 in an initial state 419 where and a front side 425 of the larger substrate 420 is substantially flat and a variable thickness material 430 including a locally thicker region 434 is disposed in a backside 426 of the larger substrate 420. During a chucking step 402, the larger substrate 420 is releasably secured to a rigid chuck 422, applying force to the variable thickness material 430 from the backside 426 and forming a bulge 424 at the front side 425 of the of the larger substrate 420.

In this specific example, a film thickness 436 of the variable thickness material 430 over the entire backside 426 of the larger substrate 420 is zero. That is, there are regions of the backside 426 of the larger substrate 420 that do not include any of the variable thickness material 430. The baseline thickness of the variable thickness material 430 from which a step height 432 of the locally thicker region 434 is measured is zero. The locally thicker region 434 is implemented as a raised structure with a substantially constant thickness (step height 432) in a desired location on the backside 426 of the larger substrate 420. In one embodiment, the locally thicker region 434 is a cylindrical structure, but of course other structures or combinations of structures are also possible and may depend on the details of a given application.

Referring to FIG. 5, a bonding process 500 begins with a larger substrate 520 in an initial state 519 where and a front side 525 of the larger substrate 520 is substantially flat and a variable thickness material 530 including a locally thicker region 534 is disposed in a backside 526 of the larger substrate 520. During a chucking step 502, the larger substrate 520 is releasably secured to a rigid chuck 522, applying force to the variable thickness material 530 from the backside 526 and forming a bulge 524 at the front side 525 of the of the larger substrate 520.

In this specific example, a film thickness 536 of the variable thickness material 530 over the entire backside 526 of the larger substrate 520 is nonzero. So, in contrast to the previous example, the variable thickness material 430 covers the entire backside 526 of the larger substrate 520 with the film thickness 536. The locally thicker region 534 is then implemented as a raised structure with a substantially constant thickness (step height 532) from on a backside film (e.g., using an additional material layer 531) in a desired location on the baseline film of the variable thickness material 530.

Referring to FIG. 6, a bonding process 600 begins with a larger substrate 620 in an initial state 619 where and a front side 625 of the larger substrate 620 is substantially flat and a variable thickness material 630 including a locally thicker region 634 is disposed in a backside 626 of the larger substrate 620. During a chucking step 602, the larger substrate 620 is releasably secured to a rigid chuck 622, applying force to the variable thickness material 630 from the backside 626 and forming a bulge 624 at the front side 625 of the of the larger substrate 620.

In this specific example, a film thickness 636 of the variable thickness material 630 over the entire backside 626 of the larger substrate 620 is zero. The locally thicker region 634 is implemented as a step pyramid structure in a desired location on the backside 626 of the larger substrate 620. The step pyramid structure has multiple levels (two here) that add up to a step height 632. Each of the levels may be formed using a different material layer, such as by patterning each of the layers successively to build the pyramid (e.g., multipatterning). Here, the locally thicker region 634 may be formed using an initial material layer and an additional material layer 631. In one embodiment, each of the levels of the locally thicker region 634 is a cylindrical structure, but of course other structures or combinations of structures are also possible and may depend on the details of a given application.

Referring to FIG. 7, a bonding process 700 begins with a larger substrate 720 in an initial state 719 where and a front side 725 of the larger substrate 720 is substantially flat and a variable thickness material 730 including a locally thicker region 734 is disposed in a backside 726 of the larger substrate 720. During a chucking step 702, the larger substrate 720 is releasably secured to a rigid chuck 722, applying force to the variable thickness material 730 from the backside 726 and forming a bulge 724 at the front side 725 of the of the larger substrate 720.

In this specific example, a film thickness 736 of the variable thickness material 730 over the entire backside 726 of the larger substrate 720 is again zero. The locally thicker region 734 is implemented as a raised structure substantially corresponding to the shape of the bulge 724. For example, the locally thicker region 734 may have a convex surface that is formed using one or more photoresist layers that received varying doses of actinic radiation to modulate the removability (e.g., solubility) of the photoresist during a development process. In one embodiment, the variable exposure process comprises a series of exposures on the same photoresist layer using different photomasks.

It should be noted that the above examples have been selected to demonstrate some of the many possible implementations of variable thickness materials in the bonding processes described herein. The concepts of the provided examples may be combined and iterated upon as will be apparent to those of skill in the art in view of this disclosure. For example, the convex thicker region shown in FIG. 7 may be combined with the backside film shown in FIG. 5 resulting in a variable thickness material that is similar to those shown in other examples, such as in FIGS. 1, 3, and 8.

FIG. 8 illustrates an example bonding process that includes bonding multiple smaller substrates, such as dies, to corresponding bulges at a front side of a larger substrate, such as a wafer, where the bulges are induced by a variable thickness material on a backside of the larger substrate in accordance with embodiments of the invention. The bonding process of FIG. 8 may be a specific implementation of other bonding processes described herein such as the bonding process of FIG. 1, for example. Similarly labeled elements may be as previously described.

Referring to FIG. 8, a bonding process 800 begins with a larger substrate 820 in an initial state 819 where a front side 825 of the larger substrate 820 is substantially flat and a variable thickness material 830 is disposed on a backside 826 of the larger substrate 820. The variable thickness material 830 has at least one locally thicker region 834 that is thicker than a film thickness 836 of other regions of the variable thickness material 830 by a step height 832. In this specific example, the variable thickness material 830 includes multiple locally thicker regions, illustrated here by including an additional locally thicker region 838. It should be noted that while the locally thicker region 834 and the additional locally thicker region 838 are schematically shown to be similar, this does not have to be the case, which is subsequently discussed in further detail.

During a chucking step 802, the larger substrate 820 is releasably secured to a rigid chuck 822. As before, because the rigid chuck 822 is resistant to physical deformation, the backside 826 of the larger substrate 820 is forced to substantially take on the shape of the rigid chuck 822 (e.g., a highly flat surface, for example). As a result, the locally thicker region 834 and the additional locally thicker region 838 of the variable thickness material 830 are pushed upward forming a bulge 824 and an additional bulge 828 at the front side 825 of the larger substrate 820. The bulge 824 has a bulge height 823 that is related to the step height 832. As already noted, while the additional bulge 828 may be the same or similar to the bulge 824 (such as having the same bulge height 823, as here), there is no requirement that this be the case.

During a bonding step 803, an upper chuck 812 is used to bond a smaller substrate 810 to the bulge 824 at the front side 825 of the larger substrate 820. The upper chuck 812 (or a different chuck) is then used to bond an additional smaller substrate 818 to the additional bulge 828 during an additional bonding step 806. Of course, bonding steps may be repeated to bond as many smaller substrates as desired to the larger substrate 820, such as during a pick and place process. While the smaller substrate 810 and the additional smaller substrate 818 are the same here, they may also be different. The flexibility to bond multiple smaller substrates (e.g., dies) that have different dimensionality to the same larger substrate (e.g., a wafer) while providing individualize scaling compensation for the different smaller substrates may be an advantage of the bonding processes described herein.

After the smaller substrate 810 and the additional smaller substrate 818 have been bonded to the bulge 824 and the additional bulge 828, respectively, the larger substrate 820 is released from the rigid chuck 822 during a dechucking step 804. Without the rigid chuck 822 applying force to the variable thickness material 830, the front side 825 of the larger substrate 820 relaxes back to (or at least towards) the substantially flat surface of the initial state 819. At this stage, the variable thickness material 830 may be removed from the backside 826 of the chucking step 802, if desired.

Multiple smaller substrates may also be bonded to a single bulge to achieve the same or similar benefits. For example, FIG. 14 illustrates an example bonding process that includes bonding multiple smaller substrates to a bulge at a front side of a larger substrate where the bulge is induced by a variable thickness material on a backside of the larger substrate in accordance with embodiments of the invention. The bonding process of FIG. 14 may be a specific implementation of other bonding processes described herein such as the bonding process of FIG. 1, for example. Similarly labeled elements may be as previously described.

Referring to FIG. 14, a bonding process 1400 begins with a larger substrate 1420 in an initial state 1419 where a front side of the larger substrate 1420 is substantially flat and a variable thickness material 1430 is disposed on a backside of the larger substrate 1420. The variable thickness material 1430 has at least one locally thicker region 1434. During a chucking step 1402, the larger substrate 1420 is releasably secured to a rigid chuck 1422. As before, the locally thicker region 1434 of the variable thickness material 1430 is pushed upward forming a bulge 1424.

In this specific example, the locally thicker region 1434 is larger than a smaller substrate 1410 so that an additional smaller substrate 1418 can also be bonded to the bulge 1424. That is, during a bonding step 1403, an upper chuck 1412 is used to bond the smaller substrate 1410 to the bulge 1424. The upper chuck 1412 (or a different chuck) is then used to bond the additional smaller substrate 1418 to the bulge 1424 during an additional bonding step 1406. Of course, bonding steps may be repeated to bond as many smaller substrates as desired to the larger substrate 1420 (including to the bulge 1424 as desired), such as during a pick and place process. After the smaller substrate 1410 and the additional smaller substrate 1418 have been bonded to the bulge 1424, the larger substrate 1420 is released from the rigid chuck 1422 during a dechucking step 1404.

FIG. 9 illustrates an example bonding process that includes bonding multiple differently sized smaller substrates to a front side of a larger substrate using a variable thickness material on the backside of the larger substrate in accordance with embodiments of the invention. The bonding process of FIG. 9 may be a specific implementation of other bonding processes described herein such as the bonding process of FIG. 1, for example. Similarly labeled elements may be as previously described.

Referring to FIG. 9, a backside 926 of a larger substrate 920 used during a bonding process 900 is shown. The larger substrate 920 has a variable thickness material 930 with to locally thicker regions (i.e., extending out of the page) disposed on the backside 926. Specifically, the variable thickness material 930 includes a locally thicker region 934 and a differently sized locally thicker region 933 that correspond to a smaller substrate 910 and an additional smaller substrate 918, respectively. In this specific example, the additional smaller substrate 918 is larger than the smaller substrate 910, but has the same shape (though this of course does not have to be the case).

The locally thicker region 934 and the differently sized locally thicker region 933 are here shown as a step pyramid structure with each level being a cylindrical structure. However, as previously described, many different configurations for the locally thicker regions are possible. The shape of the locally thicker regions may depend on a variety of factors, and may be different from the shape of smaller substrates (e.g., dies) that are bonded thereto. For example, here the locally thicker regions are circular from a top view while the smaller substrates are square.

The thickness variation within the variable thickness material 930 may be controlled to correct for the scaling issues of the smaller substrates of a given application. In various embodiments, the thickness (e.g., the step height) of the locally thicker regions may vary linearly from the center to the edges of the bonding region. That is, the further the edge of the smaller substrate is from the bond initiation point (e.g., the center), the more the thickness of the variable thickness material may decrease with respect to the center thickness. Here, the locally thicker region 934 may be thinner in the center than the differently sized locally thicker region 933 because the center of the additional smaller substrate 918 is farther from the edges of the smaller substrate.

The height variation may extend outside the bonding region (especially when the two are different shapes, as here) and may be larger or smaller than the bonding region. For example, the locally thicker region may be larger than the bonding region when the bulge formed on the front side of the larger substrate is nonuniform or otherwise undesirable near the edges. The larger locally thicker region and corresponding bulge may improve the scaling correction by avoiding bonding to the edges of the bulge. Conversely, the locally thicker region may be smaller than the bonding region when the scaling being corrected for is small since the stretching of the smaller substrate near the edges may be relatively small or smaller than in the center.

FIG. 10 illustrates an example bonding process that includes bonding multiple differently shaped smaller substrates to a front side of a larger substrate using a variable thickness material on the backside of the larger substrate in accordance with embodiments of the invention. The bonding process of FIG. 10 may be a specific implementation of other bonding processes described herein such as the bonding process of FIG. 1, for example. Similarly labeled elements may be as previously described.

Referring to FIG. 10, a backside 1026 of a larger substrate 1020 used during a bonding process 1000 is shown. The larger substrate 1020 has a variable thickness material 1030 with to locally thicker regions (i.e., extending out of the page) disposed on the backside 1026. Similar to FIG. 9, the variable thickness material 1030 of FIG. 10 includes a locally thicker region 1034 and a differently sized locally thicker region 1033 that correspond to a smaller substrate 1010 and an additional smaller substrate 1018, respectively. However, in this specific example, the additional smaller substrate 1018 has a different shape than the smaller substrate 1010.

Again, the locally thicker regions are circular from a top view, but the smaller substrates are square and rectangular. The differently sized locally thicker region 1033 is not a different shape in this example. This may be the case due to the relationship between the scaling and the distance from the center of the smaller substrate. Of course, other configurations are also possible; one of skill in the art relying on this disclosure may visualize how the same topography could be made using a locally thicker region that dropped off abruptly outside of the bonding region of the additional smaller substrate 1018. However, it may also be advantageous so have smooth transitions for the locally thicker region even outside the bonding region, as is the case with the cylindrical step pyramid configuration here, in order to maintain desirable characteristics in the corresponding bulge.

In this specific example, the extent of the differently sized locally thicker region 1033 ends before the edge of the bonding region. As already discussed, this may depend on the specific details of the scaling of a smaller substrate for a given application. The differently sized locally thicker region 1033 may also be larger than the bonding region of the additional smaller substrate 1018 in all dimensions, for example.

The shape of the locally thicker region may also be tailored to induce the desired effect on the bulge at the front side of the larger substrate. For example, FIGS. 12 and 13 illustrate example methods of bonding a smaller substrate to a larger substrate that include a variable thickness material with a locally thicker region that has alternative shapes in accordance with embodiments of the invention. The bonding processes of FIGS. 12 and 13 may each be a specific implementation of other bonding processes described herein such as the bonding process of FIG. 1, for example. Similarly labeled elements may be as previously described.

Referring to FIG. 12, a backside 1226 of a larger substrate 1220 used during a bonding process 1200 is shown. The larger substrate 1220 has a variable thickness material 1230 with a locally thicker region 1234 (i.e., extending out of the page) disposed on the backside 1226. The locally thicker region 1234 corresponds to a smaller substrate 1210. In this specific example, the locally thicker region 1234 does not extend past the edges of the bonding area of the smaller substrate 1210.

Referring now to FIG. 13, a backside 1326 of a larger substrate 1320 used during a bonding process 1300 is shown. The larger substrate 1320 has a variable thickness material 1330 with a locally thicker region 1334 (i.e., extending out of the page) disposed on the backside 1326. The locally thicker region 1334 corresponds to a smaller substrate 1310. In this specific example, the locally thicker region 1334 has a custom x-shape. Of course, other shapes are also possible and may be influenced by the type and dimensionality of the smaller substrate 1310 (e.g., type of die), the location on the larger substrate 1320, and other nearby structures, among other factors.

FIG. 11 illustrates an example method of bonding a smaller substrate to a larger substrate in accordance with embodiments of the invention. The method of FIG. 11 may be combined with other methods and performed using the systems and apparatuses as described herein. For example, the method of FIG. 11 may be combined with any of the embodiments of FIGS. 1-10. Although shown in a logical order, the arrangement and numbering of the steps of FIG. 11 are not intended to be limited. The method steps of FIG. 11 may be performed in any suitable order or concurrently with one another as may be apparent to a person of skill in the art.

Referring to FIG. 11, a method 1100 of bonding a smaller substrate (e.g., a die) to a larger substrate (e.g., a wafer) includes a chucking step 1102 of forming a bulge at a front side of the larger substrate by releasably securing a backside of the larger substrate to a rigid chuck, such as a vacuum chuck. A variable thickness material on the backside of the larger substrate induces the bulge at the front side of the larger substrate. The smaller substrate is then bonded to the bulge at the front side of the larger substrate during a bonding step 1103. One or more additional smaller substrates (with the same or different sizes and/or shapes as the initial bonded smaller substrate) may be bonded to corresponding additional bulges during optional additional bonding steps 1106. For example, the larger substrate may be a carrier wafer and multiple die substrates may be bonded to the carrier wafer using a pick and place process, for example. Each of the dies may be bonded to a bulge at the front side of the carrier wafer that is tailored to the size and shape of the die, which may afford various benefits, such as reducing or eliminating bonding distortion due to scaling, for example.

After the smaller substrate(s), are bonded to the larger substrate in the bonding step 1103 (and the optional additional bonding steps 1106, when included), the larger substrate is released from the rigid chuck during a dechucking step 1104 to allow the bulge(s) to flatten (e.g., return to or relax toward the flatness of the region before the bulge was formed during the chucking step 1102). Advantageously, this may allow for undesirable effects, such as scaling, to be mitigated or eliminated during bonding processes where one or more smaller substrates are bonded to a larger substrate using a rigid chuck (e.g., a highly flat and rigid chuck, such as a vacuum chuck).

The method 1100 may include various additional steps, some of which may involve the formation or removal of the variable thickness material on the backside of the larger substrate. For example, during an optional film formation step 1101, the variable thickness material may be formed on the backside of the larger substrate. Specifically, the variable thickness material includes at least one locally thicker region (i.e., a region that is thicker than other regions of the variable thickness material, including if the thickness of the remaining regions is zero). The variable thickness material may also be removed from the backside of the larger substrate during an optional film removal step 1105.

When included, the optional film formation step 1101 may be performed using any suitable technique or combination of techniques usable to form a film with reliable step height. In various embodiments, the variable thickness material is formed using a lithography process, and is formed using a photolithography process in some embodiments. For example, during a photolithography process, a photoresist layer may be patterned (i.e., exposed to structured actinic radiation and then developed to remove material in a material removal 1107). Multiple photolithography steps may also be performed to pattern additional photoresist layers (multipatterning 1108). Additionally or alternatively, the photolithography process may include variable exposure 1109. Variable exposure processes may vary the dose between different regions of a photoresist layer to modulate the removability of the photoresist (e.g., the solubility of the photoresist). Specifically, the depth at which the photoresist is soluble in a developer may vary based on the dose, allowing smooth transitions between thicknesses of the variable thickness material in the desired shapes and sizes. In some cases, this may have the advantage of enabling enhanced control over a corresponding bulge formed at the front side of the larger substrate using a given locally thicker region.

In some embodiments, the optional film formation step 1101 uses photolithography indirectly to form a film with reliable step height. For example, the variable thickness material may be a dielectric material (such as an oxide, nitride, oxynitride, etc.) that has been patterned using a mask that was defined using a photolithography process. In other embodiments, the optional film formation step 1101 includes a selective deposition process instead of or in addition to a photolithography process. Some examples of selective deposition processes include printing techniques, shadow mask deposition techniques, and area-selective deposition techniques.

Example embodiments of the invention are summarized here. Other embodiments can also be understood from the entirety of the specification as well as the claims filed herein.

Example 1. A method of bonding a smaller substrate to a larger substrate, the method including: forming a bulge at a front side of the larger substrate by releasably securing a backside of the larger substrate to a rigid chuck, a variable thickness material on the backside of the larger substrate inducing the bulge at the front side of the larger substrate; bonding the smaller substrate to the bulge at the front side of the larger substrate; and allowing the bulge to flatten by releasing the larger substrate from the rigid chuck.

Example 2. The method of example 1, further including: forming the variable thickness material on the backside of the larger substrate, the variable thickness material including at least one locally thicker region substantially vertically aligned with the bulge.

Example 3. The method of example 2, further including: forming the at least one locally thicker region by patterning a photoresist layer on the backside of the larger substrate using a photolithographic process.

Example 4. The method of example 3, where forming the at least one locally thicker region further includes increasing the thickness the at least one locally thicker region by patterning one or more additional photoresist layers on the backside of the larger substrate using the photolithographic process.

Example 5. The method of one of examples 3 and 4, where the photolithographic process includes a variable exposure process.

Example 6. The method of one of examples 1 to 5, where the larger substrate is releasably secured to the rigid chuck using a vacuum.

Example 7. The method of one of examples 1 to 6, where the larger substrate is a wafer and the smaller substrate is a die.

Example 8. The method of one of examples 1 to 7, further including: removing the variable thickness material from the backside of the larger substrate after the larger substrate has been released from the rigid chuck.

Example 9. The method of one of examples 1 to 8, further including: bonding one or more additional smaller substrates to one or more additional bulges on the front side of the larger substrate, the one or more additional bulges being induced by one or more additional locally thicker regions of the variable thickness material.

Example 10. The method of example 9, where the variable thickness material includes differently sized locally thicker regions.

Example 11. The method of one of examples 9 and 10, where the variable thickness material includes differently shaped locally thicker regions.

Example 12. A method of bonding a die to a wafer, the method including: forming a variable thickness material on a backside of the wafer, the variable thickness material including at least one locally thicker region; forming a bulge at a front side of the wafer by releasably securing the backside of the wafer to a rigid chuck, the at least one locally thicker region inducing the bulge at the front side of the wafer; bonding the die to the bulge at the front side of the wafer; and allowing the bulge to flatten by releasing the wafer from the rigid chuck.

Example 13. The method of example 12, forming the at least one locally thicker region by patterning a photoresist layer on the backside of the wafer using a photolithographic process.

Example 14. The method of example 13, where forming the at least one locally thicker region further includes increasing the thickness the at least one locally thicker region by patterning one or more additional photoresist layers on the backside of the wafer using the photolithographic process.

Example 15. The method of example 14, where the photolithographic process includes a variable exposure process.

Example 16. The method of one of examples 12 to 15, where the wafer is releasably secured to the rigid chuck using a vacuum.

Example 17. A method of bonding a plurality of dies to a wafer, the method including: forming a plurality of bulges on a front side of the wafer by releasably securing a backside of the wafer to a rigid chuck, a variable thickness material on the backside of the wafer inducing the plurality of bulges on the front side of the wafer; bonding the plurality of dies to respective ones of the plurality of bulges on the front side of the wafer; and allowing the plurality of bulges to flatten by releasing the wafer from the rigid chuck.

Example 18. The method of example 17, where the variable thickness material includes differently sized locally thicker regions.

Example 19. The method of one of examples 17 and 18, where the variable thickness material includes differently shaped locally thicker regions.

Example 20. The method of one of examples 17 to 19, where the wafer is releasably secured to the rigid chuck using a vacuum.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of bonding a smaller substrate to a larger substrate, the method comprising:
forming a bulge at a front side of the larger substrate by releasably securing a backside of the larger substrate to a rigid chuck, a variable thickness material on the backside of the larger substrate inducing the bulge at the front side of the larger substrate;
bonding the smaller substrate to the bulge at the front side of the larger substrate; and
allowing the bulge to flatten by releasing the larger substrate from the rigid chuck.

2. The method of claim 1, further comprising:
forming the variable thickness material on the backside of the larger substrate, the variable thickness material comprising at least one locally thicker region substantially vertically aligned with the bulge.

3. The method of claim 2, further comprising:
forming the at least one locally thicker region by patterning a photoresist layer on the backside of the larger substrate using a photolithographic process.

4. The method of claim 3, wherein forming the at least one locally thicker region further comprises increasing the thickness the at least one locally thicker region by patterning one or more additional photoresist layers on the backside of the larger substrate using the photolithographic process.

5. The method of claim 3, wherein the photolithographic process comprises a variable exposure process.

6. The method of claim 1, wherein the larger substrate is releasably secured to the rigid chuck using a vacuum.

7. The method of claim 1, wherein the larger substrate is a wafer and the smaller substrate is a die.

8. The method of claim 1, further comprising:
removing the variable thickness material from the backside of the larger substrate after the larger substrate has been released from the rigid chuck.

9. The method of claim 1, further comprising:
bonding one or more additional smaller substrates to one or more additional bulges on the front side of the larger substrate, the one or more additional bulges being induced by one or more additional locally thicker regions of the variable thickness material.

10. The method of claim 9, wherein the variable thickness material comprises differently sized locally thicker regions.

11. The method of claim 9, wherein the variable thickness material comprises differently shaped locally thicker regions.

12. A method of bonding a die to a wafer, the method comprising:
forming a variable thickness material on a backside of the wafer, the variable thickness material comprising at least one locally thicker region;
forming a bulge at a front side of the wafer by releasably securing the backside of the wafer to a rigid chuck, the at least one locally thicker region inducing the bulge at the front side of the wafer;
bonding the die to the bulge at the front side of the wafer; and
allowing the bulge to flatten by releasing the wafer from the rigid chuck.

13. The method of claim 12, forming the at least one locally thicker region by patterning a photoresist layer on the backside of the wafer using a photolithographic process.

14. The method of claim 13, wherein forming the at least one locally thicker region further comprises increasing the thickness the at least one locally thicker region by patterning one or more additional photoresist layers on the backside of the wafer using the photolithographic process.

15. The method of claim 14, wherein the photolithographic process comprises a variable exposure process.

16. The method of claim 12, wherein the wafer is releasably secured to the rigid chuck using a vacuum.

17. A method of bonding a plurality of dies to a wafer, the method comprising:
forming a plurality of bulges on a front side of the wafer by releasably securing a backside of the wafer to a rigid chuck, a variable thickness material on the backside of the wafer inducing the plurality of bulges on the front side of the wafer;
bonding the plurality of dies to respective ones of the plurality of bulges on the front side of the wafer; and
allowing the plurality of bulges to flatten by releasing the wafer from the rigid chuck.

18. The method of claim 17, wherein the variable thickness material comprises differently sized locally thicker regions.

19. The method of claim 17, wherein the variable thickness material comprises differently shaped locally thicker regions.

20. The method of claim 17, wherein the wafer is releasably secured to the rigid chuck using a vacuum.
